(19) United States
(12) Patent Application Publication
(10) Pub. No.: US 2025/0159828 A1
(43) Pub. Date: May 15, 2025

(54) METHOD FOR PREPARING DISPLAY SCREEN COVER PLATE, DISPLAY SCREEN COVER PLATE AND DISPLAY DEVICE

(71) Applicant: BOE TECHNOLOGY GROUP CO., LTD., Beijing (CN)

(72) Inventors: Weiliang Yuan, Beijing (CN); Paoming Tsai, Beijing (CN); Xiongnan Zhang, Beijing (CN); Shuang Du, Beijing (CN)

(73) Assignee: BOE TECHNOLOGY GROUP CO., LTD., Beijing (CN)

(21) Appl. No.: 18/836,482

(22) PCT Filed: Jun. 9, 2023
(86) PCT No.: PCT/CN2023/099423

§ 371 Date: Aug. 7, 2024

(30) Foreign Application Priority Data
Jun. 14, 2022 (CN) 202210673478.5

(51) Int. Cl. H05K 5/03; C08G 73/10; C08J 5/18

(52) U.S. Cl. CPC H05K 5/03; C08G 73/1007; C08G 73/1021; C08J 5/18; C08J 2379/08

(57) ABSTRACT

The present disclosure discloses a method for preparing a display screen cover plate, a display screen cover plate and a display device. The method for preparing a display screen cover plate including: condensing a dianhydride monomer with a first diamine monomer and a second diamine monomer to obtain a polyamide acid; reacting the polyimide acid with a dehydrating agent and a catalyst to obtain a polyimide polymer; dissolving the polyimide polymer in a solvent to obtain a polymer solution; coating the polymer solution onto the substrate to form a film, and peeling off to obtain the display screen cover plate; and the dianhydride monomer having a benzene ring structure and a fluorinated group connected to the benzene ring structure, the first diamine monomer having a pyridine structure, and the second diamine monomer having a benzene ring structure.

### CROSS-REFERENCE TO RELATED APPLICATION

The present application claims a priority to Chinese patent application No. 202210673478.5 filed on Jun. 14, 2022, the disclosures of which are incorporated in their entirety by reference herein.

### TECHNICAL FIELD

The present disclosure relates to the field of display technology, in particular to a method for preparing a display screen cover plate, a display cover plate and a display device.

### BACKGROUND

An organic light-emitting diode (OLED) display has many advantages such as all-solid-state, high brightness, high contrast, high response, active light emitting and no viewing angle limit, and is gradually replacing liquid crystal display (LCD) as an important form of flat panel display. Flexible OLED display has the characteristics of light and thin, impact resistance, and bendability, which is an important development direction of OLED display. The flexible display has the characteristics of bendability, high definition and high color gamut saturation. In practical application, the substrate of the flexible screen also has the shortcomings of low hardness and poor resistance to external force destruction. Therefore, the stable and reliable cover plate determines the life and comfort of the flexible screen, and the hardness, impact resistance of the existing flexible screen cover plate is low. However, the existing flexible screen cover plate has low hardness and impact resistance, and poor light transmittance, making it difficult to meet the requirements.

### SUMMARY

The object of the present disclosure is to provide a method for preparing a display screen cover plate, a display screen cover plate and a display device.

According to the first aspect, an embodiment of the disclosure provides a method for preparing a display screen cover plate, including:
condensing a dianhydride monomer with a first diamine monomer and a second diamine monomer to obtain a polyamide acid;
reacting the polyimide acid with a dehydrating agent and a catalyst to obtain a polyimide polymer;
dissolving the polyimide polymer in a solvent to obtain a polymer solution; and
coating the polymer solution onto a substrate to form a film, and peeling off the film to obtain the display screen cover plate,
the dianhydride monomer has a benzene ring structure and a fluorinated group connected to the benzene ring structure, the first diamine monomer has a pyridine structure, and the second diamine monomer has a benzene ring structure.

Optionally, the step of condensing the dianhydride monomer with a first diamine monomer and a second diamine monomer includes condensing the dianhydride monomer with the first diamine monomer and the second diamine monomer at a temperature of 0° C. to 5° C. for a period of 15 hours to 35 hours.

Optionally, the step of reacting the polyimide acid with a dehydrating agent and a catalyst includes reacting the polyimide acid with the dehydrating agent and the catalyst in a nitrogen atmosphere at a temperature of 20° C. to 40° C. for a period of 15 hours to 35 hours.

Optionally, the step of reacting the polyimide acid with a dehydrating agent and a catalyst to obtain a polyimide polymer includes: reacting the polyimide acid with the dehydrating agent and the catalyst to obtain a solution of polyimide polymer; and adding the solution of polyimide polymer to a methanol solvent to precipitate the polyimide polymer.

Optionally, the dianhydride monomer is hexafluorodianhydride, the first diamine monomer is 2-(4-aminophenyl)-5-aminopyridine, and the second diamine monomer is 2,6-diaminotoluene.

Optionally, the dehydrating agent is acetic anhydride, and the catalyst is triethylamine.

Optionally, the molar amount of the dianhydride monomer is the same as that of the diamine monomer.

Optionally, the molar ratio of the polyamide acid to the dehydrating agent to the catalyst is (0.7-1.2):(3-5):(0.7-1.2).

According to the second aspect, an embodiment of the present disclosure provides a display screen cover plate which includes a polyimide polymer, in which the polyimide polymer includes a repeating unit, and the repeating unit includes:
a first repeating unit, in which the first repeating unit is formed by the condensation of the dianhydride monomer and the first diamine monomer, the dianhydride monomer has a benzene ring structure and a fluorinated group connected to the benzene ring structure, and the first diamine monomer has a pyridine structure; and
a second repeating unit, in which at least one of the second repeating units is connected with the first repeating unit, the second repeating unit is formed by the condensation of the dianhydride monomer and the second diamine monomer, and the second diamine monomer has a benzene ring structure.

Optionally, a plurality of the first repeating units forms a first long chain, a plurality of the second repeating units forms a second long chain, and one end of the first long chain is connected with one end of the second long chain.

According to the third aspect, an embodiment of the disclosure provides a display device, including:
the display screen cover plate described above; and
a display screen, in which the cover plate is provided on the display side of the display screen.

Optionally, the device further includes: an optical film layer, in which the optical film layer is provided between the cover plate and the display screen, the cover plate is connected with the optical film layer by a first optical adhesive layer, and the optical film layer is connected with the display screen by a second optical adhesive layer; and a support layer, in which the support layer is provided on the side of the display screen away from the cover plate, and the support layer is connected with the display screen through a third optical adhesive layer.

### BRIEF DESCRIPTION OF THE DRAWINGS

FIG. 1 is a schematic diagram of a reaction device;

FIG. 2 is a schematic diagram of a reaction process;

FIG. 3a is a schematic diagram of a cover plate covering the text;

FIG. 3b is a scanning electron microscope diagram of the surface of the film;

FIG. 3c is a scanning electron microscope diagram of the thin film cross-section;

FIG. 4 is a thermogravimetric curve of the film:

FIG. 5 is a infrared spectrum of the film;

FIG. 6 is a schematic diagram of the matching between the cover plate and the display screen;

FIG. 7 is a diagram of the relationship between the different cover plate modulus and the withstanding pen drop height of the module:

FIG. 8 is another schematic diagram of the cover plate and the display screen;

FIG. 9 is another diagram of the relationship between the different cover plate modulus and the withstanding pen drop height of the module;

FIG. 10 is another schematic diagram of the matching between the cover plate and the display screen.

### REFERENCE NUMERALS

cover plate 10; first optical adhesive layer 11; second optical adhesive layer 12; third optical adhesive layer 13;
display screen 20;
optical adhesive layer 30;
glass layer 40;
support layer 50;
optical film layer 60.

### DETAILED DESCRIPTION

The technical solutions in the embodiments of the present disclosure will be described clearly and completely with reference to the accompanying drawings. Obviously, the embodiments described are only some, but not all, of the embodiments of the present disclosure. Based on the described embodiments of the present disclosure, all other embodiments obtained by those of ordinary skill in the art without creative work fall within the protection scope of the present disclosure.

The terms “first”, “second”, etc., in the description and claims of the disclosure are used to distinguish similar objects, but are not used to describe a specific order or sequence. It should be understood that such terms are interchangeable in appropriate cases so that the embodiments of the present disclosure can be implemented in an order other than those illustrated or described here. In addition, the term “and/or” in the description and claims indicates at least one of the connected objects, and the character “/” generally denotes a relationship of “or” between the preceding and following objects.

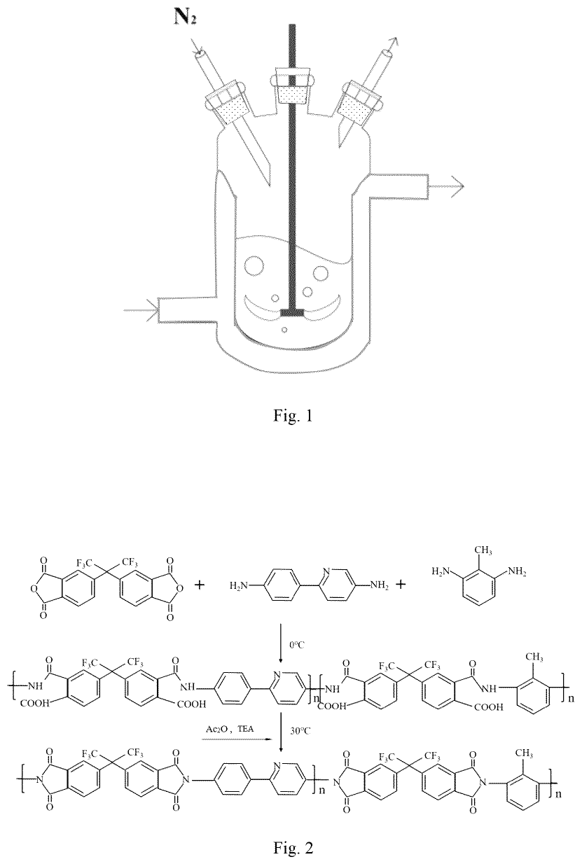

With reference to the FIGS. 1 to 10, a detailed explanation of the method for preparing display screen cover plate provided in this embodiment of the disclosure will be described through specific examples and application scenarios.

The method for preparing display screen cover plate according to an embodiment of the disclosure includes:
condensing a dianhydride monomer with a first diamine monomer and a second diamine monomer to obtain a polyamide acid;
reacting the polyimide acid with a dehydrating agent and a catalyst to obtain a polyimide polymer;
dissolving the polyimide polymer in a solvent to obtain a polymer solution; and
coating the polymer solution onto the substrate to form a film, and peeling off the film to obtain the display screen cover plate,
the dianhydride monomer has a benzene ring structure and a fluorinated group connected to the benzene ring structure, the fluorinated group can be —CF₃, the first diamine monomer has the pyridine structure, and the second diamine monomer has also a benzene ring structure.

During the preparation process, the reaction for synthesizing polyimide acid and polyimide polymer can be carried out in a three-necked flask under the nitrogen atmosphere. Before the reaction, the first and second diamine monomers can be mixed, and both need to be subjected to vacuum sublimation before polymerization. A certain amount of diamine monomer can be dissolved in N,N-dimethylacetamide (DMAc), and after the diamine monomer is completely dissolved, an equimolar amount of dianhydride monomer can be added to initiate the reaction. After the polyimide acid reacts with a dehydrating agent and a catalyst, the polyimide polymer can be precipitated from a solution containing methanol as a solvent to obtain the polyimide polymer.

The polyimide polymer is dissolved in N,N-dimethylacetamide to prepare a solution with a solid content of 15-30 wt %, for example, a solid content of 20 wt %. Then the solution is coated onto a glass substrate and the solvent is evaporated on a constant temperature heating platform at 60° C. Once the film has formed, it is peeled off. The peeled film is placed in a vacuum drying oven, the vacuum drying oven is pumped to a negative pressure state, and the high-temperature solvent removal treatment is carried out at a temperature of 140° C. to 160° C. (for example, at 150° C.). Then the polyimide polymer film, that is, a display screen cover plate, can be obtained.

The dianhydride monomer is condensed with a first diamine monomer and a second diamine monomer to obtain a polyamide acid. The dianhydride monomer has a benzene ring structure and a fluorinated group connected to the benzene ring structure, for example, the dianhydride monomer may be hexafluorodianhydride (6FDA). The first diamine monomer has a pyridine structure, and may also have a benzene ring structure, and the pyridine structure may be connected with the benzene ring structure in the first diamine monomer, for example, the first diamine monomer may be 2-(4-aminophenyl)-5-aminopyridine (PD). The second diamine monomer may have a benzene ring structure, and there are two amino groups on the benzene ring structure in the second diamine monomer, for example, the second diamine monomer may be 2,6-diamino-toluene (2,6-DAT). The polyimide acid is then reacted with a dehydrating agent and a catalyst, for example, acetic anhydride (Ac₂O) can be used as the dehydrating agent and triethylamine (TEA) can be used as the catalyst, to obtain the polyimide polymer. The polyimide polymer is dissolved in a solvent that can be N,N-dimethylacetamide to obtain a polymer solution. The polymer solution is coated onto a substrate to form a film which is peeled off to obtain a display screen cover plate.

In the method for preparing display screen cover plate according to the embodiments of this disclosure, the dianhydride monomer has a benzene ring structure and a fluorinated group connected to the benzene ring structure, the first diamine monomer has a pyridine structure, and the second diamine monomer has also a benzene ring structure. The linear rod-like structure of phenyl-pyridine enhances the rigidity of the polymer molecular chains. Diamines having pyridine and benzene ring structures can make the polyimide molecular chains tend to be orderly and tightly arranged. The formation of hydrogen bonds between the polymer chains enhances intermolecular forces such as van der Waals forces and dispersion forces, stabilizing the conformation of the molecular chain segments. The introduction of fluorinated cycloaliphatic structures can reduce the intramolecular or intermolecular charge transfer forces within the structure, making it easy to prepare transparent and colorless polyimide film cover plates with high light transmittance. The increased rigidity of the polymer chains enhances the mechanical and thermal properties of the polyimide film, resulting in a cover plate with outstanding hardness, high transparency, and a high modulus. The outer surface hardness of the cover plate can reach a level of 6H, which can achieve excellent high modulus and good flexibility at the same time, greatly improving the impact resistance of the cover plate and providing better protection for the display screen. When the cover plate is matched with the display screen, during the whole impact process, the cover plate can prevent the transmission of impact energy, and a large amount of energy can be absorbed in the process of interaction, so as to improve the impact resistance of the cover plate and effectively protect the display screen.

In some embodiments, the steps of condensing a dianhydride monomer with a first diamine monomer and a second diamine monomer includes condensing the dianhydride monomer with the first diamine monomer and the second diamine monomer at a temperature of 0° C. to 5° C. for a period of 15 hours to 35 hours, for example, condensing the dianhydride monomer with the first diamine monomer and the second diamine monomer at a temperature of 0° C. for a period of 24 hours.

Optionally, the steps of reacting the polyimide acid with a dehydrating agent and a catalyst includes reacting the polyimide acid with the dehydrating agent and the catalyst in a nitrogen atmosphere at a temperature of 20 to 40° C. for a period of 15 hours to 35 hours, for example, reacting the polyimide acid with the dehydrating agent and the catalyst in a nitrogen atmosphere at a temperature of 30° C. for a period of 24 hours.

Optionally, the steps of reacting the polyimide acid with a dehydrating agent and a catalyst to obtain a polyimide polymer includes: reacting the polyimide acid with the dehydrating agent and the catalyst to obtain a solution of polyimide polymer, which can form a heterocyclic structure including N atoms by a reaction of carboxyl groups and amine groups in the polyimide acid, thereby enhancing the mechanical strength of the polyimide polymer; and adding the solution of polyimide polymer into a methanol solvent to precipitate the polyimide polymer, which can increase the purity of the polyimide polymer and peel off the polyimide polymer easily.

Optionally, the dianhydride monomer is hexafluorodianhydride, the first diamine monomer is 2-(4-aminophenyl)-5-aminopyridine, and the second diamine monomer is 2,6-diaminotoluene.

Optionally, the dehydrating agent is acetic anhydride, and the catalyst is triethylamine.

The molar amount of the dianhydride monomer and the molar amount of the diamine monomer can be reasonably selected according to the actual situation, for example, the molar amount of the dianhydride monomer is the same as that of the diamine monomer.

The molar ratio of the polyamide acid to the dehydrating agent to the catalyst is (0.7-1.2):(3-5):(0.7-1.2), for example, the molar ratio of the polyamide acid to the dehydrating agent to the catalyst is 1:4:1.

The specific preparation process including the following steps.

The reaction device can be shown in FIG. 1, and FIG. 2 shows the synthesis process of the polyimide polymer. The dianhydride monomer is hexafluorodianhydride (6FDA), the first diamine monomer can be 2-(4-aminophenyl)-5-aminopyridine, and the second diamine monomer can be 2,6-diamino-toluene, and the entire reaction is carried out in a three-necked flask under a nitrogen atmosphere. The moisture impurities can be removed through vacuum sublimation before polymerization. A certain amount of 2,6-DAT is dissolved in N,N-dimethylacetamide (DMAc), and after the diamine is completely dissolved, an equimolar amount of 6FDA can be added. The reaction is carried out at a temperature of 0° C. for a period of 24 hours to obtain a mixed solution with a solid content of 25.0 wt %, resulting in the formation of polyimide acid (PAA). Subsequently, the dehydrating agent acetic anhydride (Ac₂O) and the catalyst triethylamine (TEA) are added, with a molar ratio of PAA:TEA:Ac₂O of 1:1:4. The reaction is continued under a nitrogen atmosphere at an elevated temperature of 30° C. for another 24 hours. The resulting solution is then precipitated in a methanol solvent and dried to obtain polyimide. The polyimide polymer can be dissolved in N,N-dimethylacetamide to form a solution with a solid content of 20 wt %, the solution is then coated onto a glass substrate, and the solvent is evaporated on a constant temperature heating platform at 60° C. After the film forms, it is peeled off. The peeled film is placed in a vacuum drying oven, the vacuum drying oven is pumped to a negative pressure state, and the high-temperature solvent removal treatment is carried out at a temperature of 150° C. Then the polyimide polymer film, that is, a display screen cover plate, can be obtained.

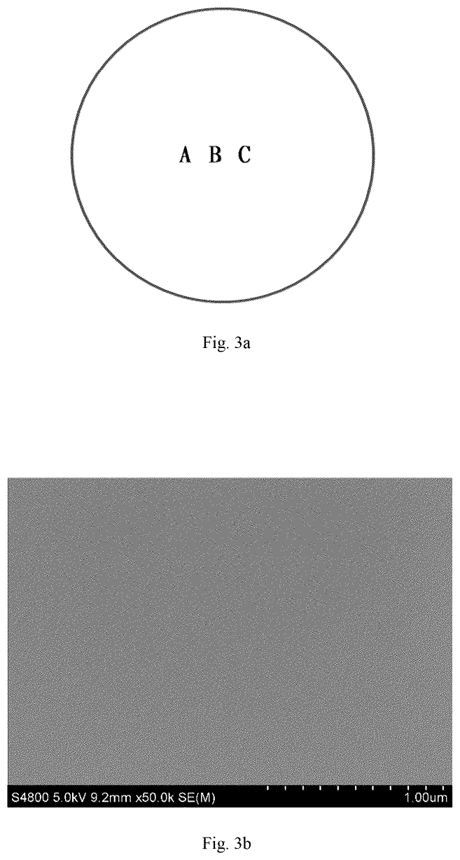

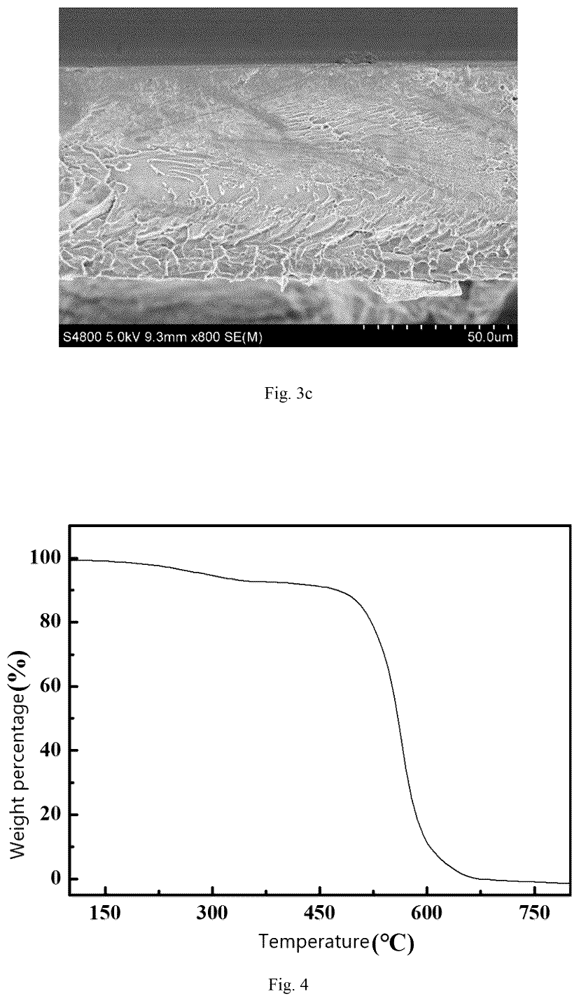

As can be seen from FIG. 3a, the prepared polyimide film is a transparent film structure with a smooth surface without defects. When the film is placed on the paper with the text, the words “ABC” on the paper can be clearly seen through the film. The SEM characterization of the film surface is shown in FIG. 3b, and it can be seen that the surface of the film is smooth and flat, with a dense structure and no wrinkles. The SEM characterization of the film cross-section is shown in FIG. 3c, and it can be seen that the polyimide film prepared by solvent volatilization has a dense structure, with no defects such as holes or needle-like holes, and the overall structure is regular, orderly and uniform. Some folds of the film cross-section are caused by the manual truncation of the film after freezing in liquid nitrogen, and are not inherent in the material itself.

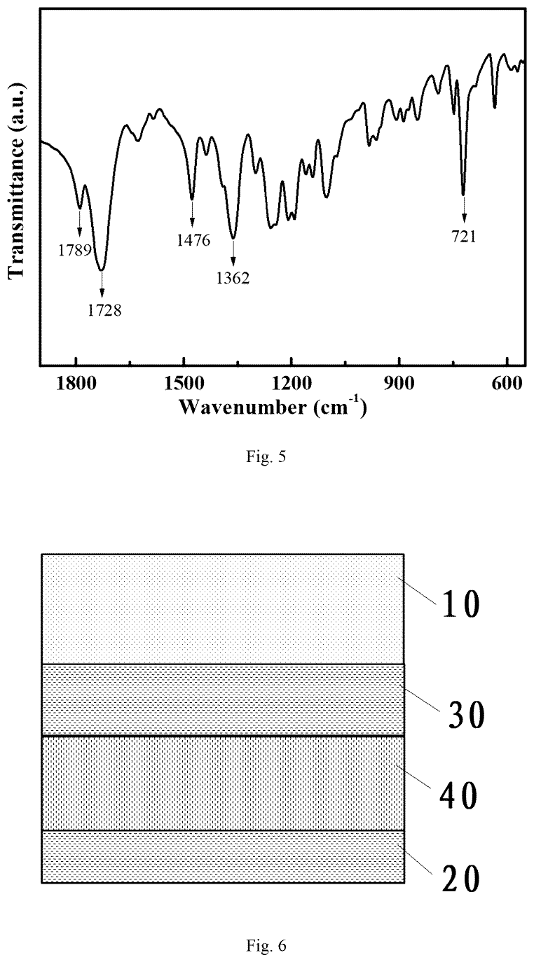

As shown in FIG. 4, the characterization results indicate that the film experiences a part of weight loss between 150° C. and 260° C., which is due to the incomplete evaporation of some solvents. A significant weight loss experiences around 450° C., at which point the polyimide material starts to carbonize and decompose, demonstrating its good high temperature resistance. As shown in FIG. 5, several characteristic peaks are clearly seen in the infrared spectroscopy characterization results. At 1789 cm⁻¹, there is an asymmetric stretching vibration peak of C═O in the imine group. At 1728 cm¹, there is a symmetric stretching vibration peak of C═O in the imine group. At 1362 cm⁻¹, there is a stretching vibration peak of C—N in the imine group. At 1537 cm¹, there is a bending vibration peak of N—H. At 721 cm⁻¹, there is a stretching vibration peak of the imine ring. At 1476 cm⁻¹, there is a C—H bond peak on the aromatic ring. At 1240 cm⁻¹, there is also a stretching vibration peak of —CF₃. The analysis of the infrared spectroscopy results confirms the presence of characteristic peaks for the polyimide material.

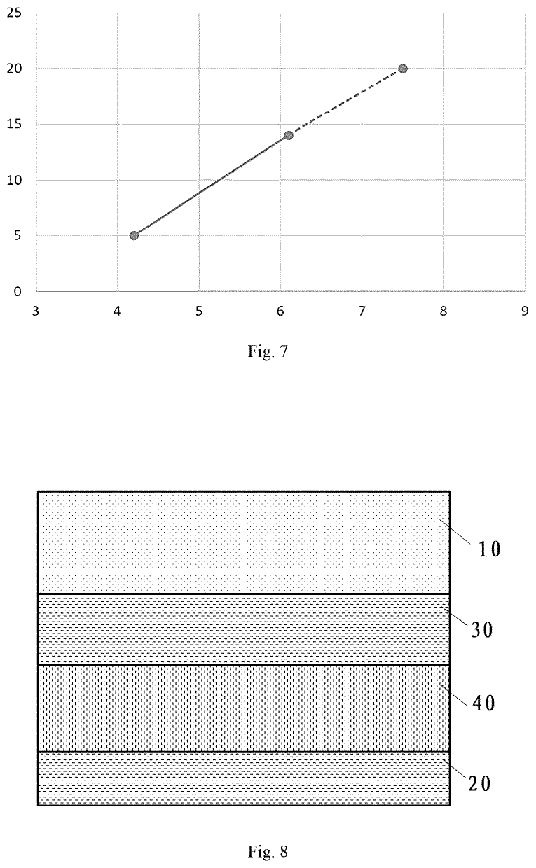

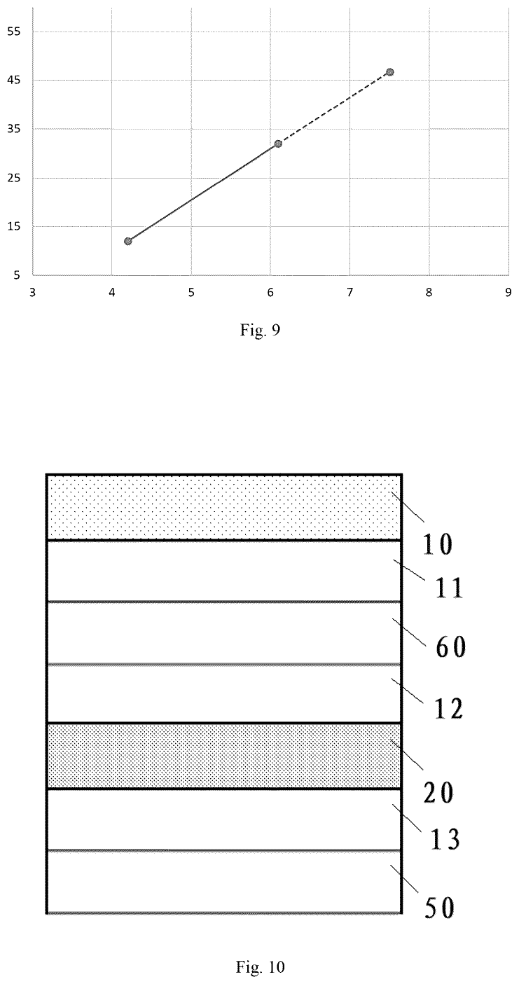

As shown in FIG. 6, it is a schematic diagram of a module structure where cover plate 10 is matched with a display screen 20. The thickness of the cover plate 10 is 80 μm, the thickness of the optical adhesive layer 30 is 50 μm, and the thickness of the glass layer 40 is 30 μm. The experiments test the withstanding pen drop height of different cover plate modulus. When the cover plate modulus is 4.2 Gpa, withstanding pen drop height is 5 cm, and when the cover plate modulus is 6.1 Gpa, the withstanding pen drop height is 14 cm. When the designed polyimide film modulus is above 7 Gpa, the withstanding pen drop height of module can be further improved, and FIG. 7 shows the relationship between different cover plate modulus of module structure and the withstanding pen drop height of the module. As shown in FIG. 8, it is a schematic diagram of a module structure where cover plate 10 is matched with a display screen 20. The thickness of the cover plate 10 is 80 μm, the thickness of the optical adhesive layer 30 is 50 μm, and the thickness of the glass layer 40 is 70 μm. The experiments test the withstanding pen drop height of different cover plate modulus. When the cover plate modulus is 4.2 Gpa, the withstanding pen drop height is 12 cm. When the cover plate modulus is 6.1 Gpa, the withstanding pen drop height is 32 cm. When the designed polyimide film modulus is above 7 Gpa, the withstanding pen drop height of module can be further improved. FIG. 9 shows the relationship between different cover plate modulus of module structure and the withstanding pen drop height of the module.

The embodiment of the disclosure provides a display screen cover plate which includes a polyimide polymer, in which the polyimide polymer includes a repeating unit, and the repeating unit includes:
a first repeating unit, where the first repeating unit is formed by the condensation of the dianhydride monomer and the first diamine monomer, the dianhydride monomer has a benzene ring structure and a fluorinated group connected to the benzene ring structure, and the first diamine monomer has a pyridine structure;
a second repeating unit, where at least one of the second repeating units is connected with the first repeating unit, the second repeating unit is formed by the condensation of the dianhydride monomer and the second diamine monomer, and the second diamine monomer has a benzene ring structure.

The cover plate includes the polyimide polymer, the first repeating unit is formed by the condensation of the dianhydride monomer and the first diamine monomer, the dianhydride monomer has a benzene ring structure and a fluorinated group connected to the benzene ring structure, the fluorinated group can be —CF₃, and the first diamine monomer has a pyridine structure. A second repeating units is connected with the first repeating unit, the second repeating unit is formed by the condensation of the dianhydride monomer and the second diamine monomer, and the second diamine monomer has a benzene ring structure. Diamines with pyridine and benzene structures can make the polyimide molecular chains tend to be orderly and tightly arranged. The formation of hydrogen bonds between the polymer chains enhances intermolecular forces such as van der Waals forces and dispersion forces, stabilizing the conformation of the molecular chain segments. The introduction of fluorinated cycloaliphatic structure can reduce the intramolecular or intermolecular charge transfer forces within the structure, making it easy to prepare a transparent and colorless polyimide film cover plates. The increased rigidity of the polymer chains enhances the mechanical and thermal properties of the polyimide film. The cover plate has outstanding hardness, high transparency, and a high modulus, which greatly improve the impact resistance of the cover plate, and make the display screen be better protected.

In some embodiments, a plurality of the first repeating units form a first long chain, a plurality of the second repeating units form a second long chain. One end of the first long chain is connected with one end of the second long chain, which facilitates the orderly arrangement and close packing of the polyimide molecular chains, thereby stabilizing the conformation of the molecular chain segments.

The embodiment of the present disclosure provides a display device, as shown in FIGS. 6 and 8, which includes a cover plate 10 described in the above embodiment; and a display screen 20, where the cover plate 10 is provided on the display side of the display screen 20. The display screen 20 can be a flexible display screen, and the display screen 20 can be effectively protected through the cover plate 10, and the light transmittance is good. Optionally, the cover plate 10 can be bonded to the display side of the display screen 20 through an optical adhesive layer 30, a glass layer 40 can be arranged between the optical adhesive layer 30 and the display screen 20. The display screen 20 can be protected through the cover plate 10, and the light transmittance is good.

In some embodiments, as shown in FIG. 10, the display device can also include: an optical film layer 60 and a support layer 50, where the optical film layer 60 is arranged between cover plate 10 and display screen 20, the cover plate 10 is connected with optical film layer 60 through a first optical adhesive layer 11, the optical film layer 60 is connected with display screen 20 through a second optical adhesive layer 12, and the optical film layer 60 can be a polarizing film. The support layer 50 is arranged on one side of the display screen 20 away from the cover plate 10, and the support layer 50 is connected with the display screen 20 through a third optical adhesive layer 13, and the support layer 50 can have a supporting effect.

The display 20 can include, but is not limited to, OLED display screen, LCD display screen, LED display screen, PDP display screen or Mini LED display screen.

The embodiments of this disclosure are described above with reference to the accompanying drawings, but this disclosure is not limited to the foregoing specific implementations, and the foregoing specific implementations are only illustrative and not restrictive. Under the enlightenment of this disclosure, a person of ordinary skill in the art can make many forms without departing from the purpose of this disclosure and the protection scope of the claims, all of which fall within the protection of this disclosure.

1. A method for preparing a display screen cover plate, comprising:
condensing a dianhydride monomer with a first diamine monomer and a second diamine monomer to obtain a polyamide acid;
reacting the polyimide acid with a dehydrating agent and a catalyst to obtain a polyimide polymer;
dissolving the polyimide polymer in a solvent to obtain a polymer solution; and
coating the polymer solution onto a substrate to form a film, and peeling off the film to obtain the display screen cover plate,
wherein the dianhydride monomer has a benzene ring structure and a fluorinated group connected to the benzene ring structure, the first diamine monomer has a pyridine structure, and the second diamine monomer has a benzene ring structure.

2. The method according to claim 1, wherein a step of condensing the dianhydride monomer with the first diamine monomer and the second diamine monomer comprises:
condensing the dianhydride monomer with the first diamine monomer and the second diamine monomer at a temperature of 0° C. to 5° C. for a period of 15 hours to 35 hours.

3. The method according to claim 1, wherein a step of reacting the polyimide acid with the dehydrating agent and the catalyst comprises:
reacting the polyimide acid with the dehydrating agent and the catalyst in a nitrogen atmosphere at a temperature of 20° C. to 40° C. for a period of 15 hours to 35 hours.

4. The method according to claim 1, wherein a step of reacting the polyimide acid with the dehydrating agent and the catalyst to obtain the polyimide polymer comprises:
reacting the polyimide acid with the dehydrating agent and the catalyst to obtain a solution of polyimide polymer; and
adding the solution of polyimide polymer to a methanol solvent to precipitate the polyimide polymer.

5. The method according to claim 1, wherein the dianhydride monomer is hexafluorodianhydride, the first diamine monomer is 2-(4-aminophenyl)-5-aminopyridine, and the second diamine monomer is 2,6-diaminotoluene.

6. The method according to claim 1, wherein the dehydrating agent is acetic anhydride, and the catalyst is triethylamine.

7. The method according to claim 1, wherein a molar amount of the dianhydride monomer is the same as that of the diamine monomer.

8. The method according to claim 1, wherein a molar ratio of the polyamide acid to the dehydrating agent to the catalyst is (0.7-1.2):(3-5):(0.7-1.2).

9. A display screen cover plate which comprises a polyimide polymer, wherein the polyimide polymer comprises a repeating unit, and the repeating unit comprises:
a first repeating unit, wherein the first repeating unit is formed by an condensation of a dianhydride monomer and a first diamine monomer, the dianhydride monomer has a benzene ring structure and a fluorinated group connected to the benzene ring structure, and the first diamine monomer has a pyridine structure; and
a second repeating unit, wherein at least one of the second repeating units is connected with the first repeating unit, the second repeating unit is formed by a condensation of the dianhydride monomer and a second diamine monomer, and the second diamine monomer has a benzene ring structure.

10. The cover plate according to claim 9, wherein a plurality of the first repeating units forms a first long chain, a plurality of the second repeating units forms a second long chain, and one end of the first long chain is connected with one end of the second long chain.

11. A display device, comprising:
the display screen cover plate according to claim 9;
a display screen, wherein the cover plate is provided on a display side of the display screen.

12. The display device according to claim 11, further comprising:
an optical film layer, wherein the optical film layer is provided between the cover plate and the display screen, the cover plate is connected with the optical film layer by a first optical adhesive layer, and the optical film layer is connected with the display screen by a second optical adhesive layer; and
a support layer, wherein the support layer is provided on the side of the display screen away from the cover plate, and the support layer is connected with the display screen through a third optical adhesive layer.

13. The cover plate according to claim 9, wherein the dianhydride monomer is hexafluorodianhydride, the first diamine monomer is 2-(4-aminophenyl)-5-aminopyridine, and the second diamine monomer is 2,6-diaminotoluene.

14. The cover plate according to claim 9, wherein a molar amount of the dianhydride monomer is the same as that of the diamine monomer.

15. The cover plate according to claim 9, wherein a molar ratio of the polyamide acid to the dehydrating agent to the catalyst is (0.7-1.2):(3-5):(0.7-1.2).

16. The display device according to claim 11, wherein a plurality of the first repeating units forms a first long chain, a plurality of the second repeating units forms a second long chain, and one end of the first long chain is connected with one end of the second long chain.

17. The display device according to claim 11, wherein the dianhydride monomer is hexafluorodianhydride, the first diamine monomer is 2-(4-aminophenyl)-5-aminopyridine, and the second diamine monomer is 2,6-diaminotoluene.

18. The display device according to claim 11, wherein a molar amount of the dianhydride monomer is the same as that of the diamine monomer.

19. The display device according to claim 11, wherein a molar ratio of the polyamide acid to the dehydrating agent to the catalyst is (0.7-1.2):(3-5):(0.7-1.2).
